(19) United States
(12) Patent Application Publication
(10) Pub. No.: US 2016/0218230 A1
(43) Pub. Date: Jul. 28, 2016

(54) METHOD OF PRODUCING GLASS SUBSTRATE FOR PATTERNED SOLAR CELL AND THIN-FILM SOLAR CELL USING THE GLASS SUBSTRATE

(71) Applicant: RESEARCH & BUSINESS FOUNDATION SUNGKYUNKWAN UNIVERSITY, Suwon-si (KR)

(72) Inventors: Junsin YI, Seoul (KR); Hyeongsik Park, Bucheon-si (KR); Shihyun Ahn, Suwon-si (KR); Sunbo Kim, Suwon-si (KR)

(73) Assignee: RESEARCH & BUSINESS FOUNDATION SUNGKYUNKWAN UNIVERSITY, Suwon-si (KR)

(21) Appl. No.: 15/002,545

(22) Filed: Jan. 21, 2016

(30) Foreign Application Priority Data
Jan. 22, 2015 (KR) 10-2015-0010717

(51) Int. Cl. H01L 31/0236; H01L 31/0445; H01L 31/0224

(52) U.S. Cl. CPC H01L 31/02366; H01L 31/022483; H01L 31/022475; H01L 31/0445

(57) ABSTRACT

The present invention relates to a method of etching a glass substrate for a patterned solar cell. According to one exemplary embodiment of the present invention, the method of etching a glass substrate for a patterned solar cell includes an etching process in which the glass substrate is etched by an etching solution that contains hydrofluoric acid; and a cleaning process in which by-products that are formed during the etching process are washed off by a cleaning solution that contains hydrochloric acid.

### CROSS-REFERENCE TO RELATED APPLICATION

This application claims the benefit under 35 USC 119(a) of Korean Patent Application No. 10-2015-0010717, filed on Jan. 22, 2015, the entire disclosure of which is incorporated herein by reference for all purposes.

### BACKGROUND

1. Field of the Invention

The present invention relates to a method of producing a glass substrate for a solar cell, wherein the method is capable of forming a patterned layer by a simple process.

Also, the present invention relates to a thin-film solar cell that includes the glass substrate.

2. Discussion of Related Art

Recently, with the prediction of the depletion of existing energy sources such as oil or coal, there has been a growing interest in alternative energy sources. Among them, solar cells in particular have received attention because they do not cause environmental pollution and their energy source is abundant. Solar cells can be categorized into solar thermal cells, which use solar heat to generate steam that is necessary for the rotation of a turbine, and photovoltaic cells, which make use of properties of a semiconductor to convert sunlight to electrical energy. However, solar cells generally refer to photovoltaic cells, which will be referred to as solar cells hereinafter.

Like diodes, solar cells have a junction structure of a p-type semiconductor and an n-type semiconductor. When a light is incident on such a solar cell, the light interacts with a material that constitutes a semiconductor of the solar cell, generating a negatively charged electron and a positively charged hole, which is created as a result of the escape of the electron, and the movements thereof cause a current to flow. This is called a photovoltaic effect. Among the p-type and n-type semiconductors which constitute a solar cell, the electron moves toward the n-type semiconductor and the hole is attracted toward the p-type semiconductor so that they move respectively to electrodes that are connected with one of the n-type and p-type semiconductors. When the electrodes are connected to each other by an electric wire, electricity flows, and thus electric power can be obtained.

Short-circuit current density of such a solar cell varies depending on the pattern, which is formed on a glass substrate that is used in the solar cell. Much research has been proposed to improve the short-circuit current density, representative thereof including a method of forming a structure on a glass substrate by dry etching or a method of forming a pattern by an imprinting technique. However, the production of solar cells using such methods is uneconomical when cost is considered, and the process is complex.

In addition, existing methods of producing a glass substrate for a solar cell aimed at reducing costs include a method of forming a pattern on a glass substrate using the anodization of aluminum. Since an aluminum sheet and an electrolyte need to be prepared and voltage and the like need to be applied to both sides of the glass substrate to produce such a glass substrate, it is difficult to secure relevant conditions therefor.

### SUMMARY OF THE INVENTION

The present invention is directed to providing a method of producing a glass substrate for a solar cell, wherein the method simplifies the process of pattern formation on the glass substrate, and a thin-film solar cell that employs the glass substrate.

According to an exemplary embodiment of the present invention, a method of etching a glass substrate for a patterned solar cell may include an etching process and a cleaning process.

The etching process may be a process in which a glass substrate is etched by an etching solution that contains hydrofluoric acid (HF). The process is not limited to a particular etching method, as long as the method is capable of etching the glass substrate by an etching solution that contains HF. In one exemplary embodiment, the etching solution may contain hydrochloric acid (HCl) at 300 parts by weight or more with respect to 100 parts by weight of the above HF.

In one exemplary embodiment, the method of etching a glass substrate for a patterned solar cell according to an exemplary embodiment of the present invention may further include a mask forming process.

The mask forming process may be a process in which the aforementioned glass substrate is immersed in a solution that contains polymer particles, is removed from the solution, and is then dried to prepare a polymer particle mask. For example, in the mask forming process, a plurality of polymer particle masks may be prepared by immersing the glass substrate in the solution to adsorb the polymer particles to a surface of the glass substrate, removing the glass substrate from the solution, and then drying the glass substrate while the plurality of polymer particles are still adsorbed to the glass substrate. In one exemplary embodiment, a size and type of the polymer particles may be variously applied depending on a size and shape of the pattern to be formed on the glass substrate.

The cleaning process may be a process in which cleaning is carried out using a cleaning solution that contains HCl. According to one exemplary embodiment, in addition to HCl, the cleaning solution may contain one or more among deionized water, HF, and acetic acid (CH₃COOH), and for example, it may contain all of the above HCl, deionized water, HF, and acetic acid.

In one exemplary embodiment, one or more by-products on the glass substrate may be removed as a result of the etching and cleaning processes. In one exemplary embodiment, the one or more by-products may be SiH₆, SiHF₄, SiHF₅ or the like, and are not particularly limited to a certain type, as long as they are by-products that are produced during the etching process.

In one exemplary embodiment, the roughness of the surface of the glass substrate may be reduced as a result of the etching and cleaning processes.

According to another exemplary embodiment of the present invention, a thin-film solar cell may include a glass substrate of an exemplary embodiment of the present invention. In one exemplary embodiment, the thin-film solar cell may include a glass substrate that includes a transparent electrode layer deposited thereon. In one exemplary embodiment, the transparent electrode layer may include any one or more among zinc oxide (ZnO), aluminum-doped zinc oxide (AZO), gallium-doped zinc oxide (GZO), boron-doped zinc oxide (BZO), indium tin oxide (ITO), indium gallium zinc oxide (IGZO), and zirconium-doped indium tin oxide (ITO:Zr). However, as long as the layer may be used as a transparent electrode layer, its application is not limited to the above exemplary embodiment.

The method of producing a glass substrate for a solar cell of the present invention can form a pattern on a glass substrate by a simple process only, thus resulting in a low production cost and a simplification of the process of producing a glass substrate that is used as a transparent electrode in an existing solar cell with a high light-conversion efficiency.

Also, the thin-film solar cell including a glass substrate of the present invention exhibits a light-conversion efficiency that is equivalent to, or greater than, that of existing solar cells.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 shows photographed images showing degrees of removal of by-products from surfaces of glass substrates according to an exemplary embodiment of the present invention and comparative examples at various concentrations of hydrochloric acid contained in an etching solution;

FIG. 2 is a graph showing measured absorbance of glass substrates of the exemplary embodiment and the comparative examples; and

FIG. 3 is a graph showing measured transmittance of the glass substrate of the exemplary embodiment at various concentrations of hydrochloric acid contained in a cleaning solution.

### DETAILED DESCRIPTION OF EXEMPLARY EMBODIMENTS

Hereinafter, an exemplary embodiment of the present invention will be described in detail with reference to the accompanying drawings. While the exemplary embodiment of the present invention may be subjected to various modifications, only a particular exemplary embodiment will be described in detail hereinafter. However, there is no intention to limit the present invention to a particular exemplary embodiment, and it should be understood that the scope of the present invention encompasses all modifications, equivalents or alterations made within the spirit and scope of the present invention.

Terms such as “a/the first” and “a/the second” may be used to describe various elements of the present invention, but the elements should not be limited to the terms. Such terms are used to merely distinguish one element from the other(s). For example, “the first element” may also be named “the second element,” and similarly, “the second element” may also be named “the first element,” without departing from the scope of the present invention.

The terms in the present invention are used to merely describe particular exemplary embodiments and are not intended to limit the present invention. The expression in the singular form covers the expression in the plural form unless otherwise indicated. In describing the present invention, it will be understood that terms such as “contain,” “containing,” “include,” “including,” “comprise,” “comprising,” “have” and “having” specify that the features, elements and the like disclosed herein are present, but the terms do not preclude the possibility that one or more other features, elements and the like are also present or may be introduced, within the scope of the present invention.

Unless defined otherwise, all terms, including technical or scientific terms, used herein have the same meaning as commonly understood by a person of ordinary skill in the technical field to which the present invention belongs. Generally used terms such as those defined in a dictionary shall be construed as having the same meaning in the context of the relevant art and, unless explicitly defined otherwise, do not have an idealistic or excessively formalistic meaning.

Glass substrates according to an exemplary embodiment of the present invention and comparative examples were produced as follows:

### EXAMPLE

Firstly, a mixed solution of deionized water and isopropyl alcohol and a glass substrate were prepared in a container, and polymers differing in size (each were sized 1.2 μm and 1.8 μm) were mixed with the mixed solution. Polystyrene (silica microspheres by Polysciences, Inc.) were used as the polymers. The glass substrate was immersed in the mixed solution, which was mixed with the polymers, and then removed from the solution so that polymer particles were adsorbed to a surface of the glass substrate. The glass substrate was dried in a drier whose temperature was maintained at 25° C. to prepare a polymer particle mask on the glass substrate. Then, the glass substrate was immersed in an etching solution that was prepared by mixing hydrofluoric acid (HF) and hydrochloric acid (HCl) to remove, by etching, a glass portion of the glass substrate that the polymer particle mask was not formed on. In this case, the concentration of HF in the etching solution was 10 wt % and the concentration of HCl was 10 wt %, 20 wt %, and 30 wt % each with respect to the weight of the total composition. In order to clean the glass substrate which completed the etching process, a cleaning solution containing a mixture of HCl and deionized water, which were mixed at a ratio of 1:50, was prepared. Then, the glass substrate was cleaned with the cleaning solution for 5 minutes, and the glass substrate was treated with HCl for a second time. Lastly, the glass substrate was cleaned with a cleaning solution containing acetone, isopropyl alcohol, and distilled water to produce a patterned glass substrate.

### Comparative Example 1

Comparative Example 1 is a glass substrate that was prepared by etching with an etching solution that contained only HF, and did not contain HCl, as compared with the example above. Since the rest of the conditions of Comparative Example 1 are the same as those of the example above, repetitive descriptions thereof will be omitted.

### Comparative Examples 2 to 4

Comparative Example 2 is a glass substrate that was prepared by a standardized cleaning process that uses, as a cleaning solution, an existing cleaning solution that contains a mixture of acetone, methanol, and deionized water to clean the glass substrate. Since the rest of the conditions of Comparative Example 2 are the same as those of the example above, repetitive descriptions thereof will be omitted.

Comparative Example 3 was prepared by cleaning a glass substrate using, as a cleaning solution, a mixed solution of nitric acid and deionized water, which were mixed at a ratio of 1:50. Since the rest of the conditions of Comparative Example 3 are the same as those of the example above, repetitive descriptions thereof will be omitted.

Comparative Example 4 was prepared by cleaning a glass substrate using, as a cleaning solution, a mixed solution of acetic acid and deionized water, which were mixed at a ratio of 1:50. Since the rest of the conditions of Comparative Example 4 are the same as those of the example above, repetitive descriptions thereof will be omitted.

### Comparison of Glass Substrate Surfaces of Comparative Example 1 and Example at Various Hydrochloric Acid Concentrations

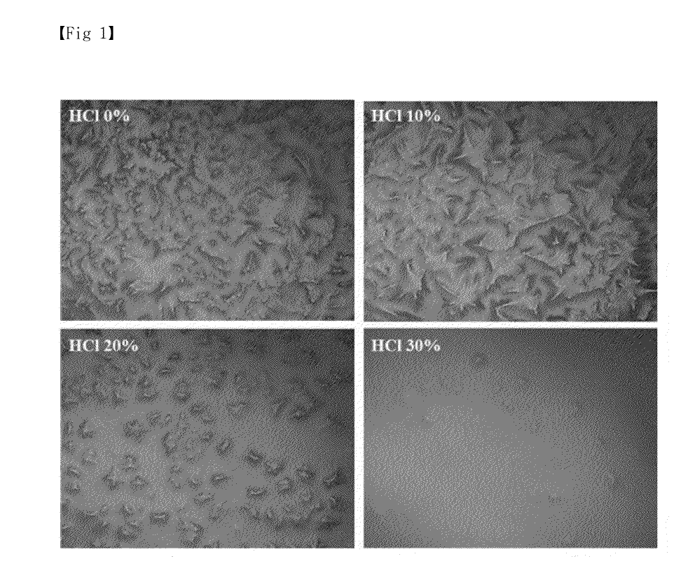

FIG. 1 shows photographed images of degrees of removal of by-products from surfaces of glass substrates of an exemplary embodiment (“example”) of the present invention and comparative examples at various concentrations of HCl contained in the etching solution. Among the images, HCl 0% corresponds to the comparative example for which an etching solution containing no HCl was used, and each of HCl 10%, 20%, 30% corresponds to the concentration of HCl for the above-described example.

Referring to FIG. 1, when the glass substrate was etched using an etching solution containing no HCl, as in the case of Comparative Example 1, it can be seen that the surface of the glass substrate is uneven and rough, and thus a surface roughness is large. Also, when the glass substrate was etched by the etching solution of the above-described example where the concentration of HCl is 10 wt % or 20 wt %, it can be seen that a surface uniformity is improved as compared with that of Comparative Example 1, but the surface is still rough, and thus a surface roughness is large. When the etching solution of the example whose concentration of HCl is 30 wt % was used to etch the glass substrate, it can be seen that an unevenness of the substrate surface disappeared and an overall uniformity of the surface was improved. In other words, when an etching solution whose HCl concentration is 30 wt % or more was used to clean a substrate, an improved surface uniformity in comparison to other cases can be seen. It is assumed that the surface roughness of the glass substrate is attributed to HF that is contained in the etching solution of the example, which was used in the etching process of the glass substrate and reacted with Si atoms of the glass on the surface of the glass substrate to form SiH₆, SiHF₄, SiF₆ as by-products which were adsorbed to the surface of the glass substrate. It is determined that by etching a glass substrate including by-products formed thereon with an etching solution containing HCl to induce a primary reaction between the HCl in the etching solution and the by-products, and by cleaning the glass substrate with the cleaning solution of the example that contains HCl to induce a secondary reaction between the HCl in the cleaning solution and the by-products, the by-products were removed effectively by the two above reactions involving HCl, and thus an improved surface uniformity and a reduced surface roughness of the glass substrate were achieved.

### Comparison of Absorbance of Example and Comparative Examples 2 to 4

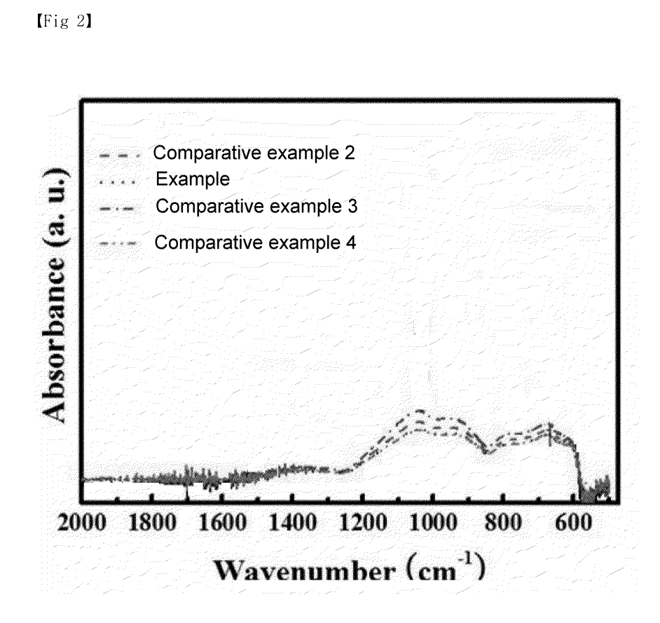

FIG. 2 is a graph showing measured absorbance of glass substrates that were cleaned with a cleaning solution containing HCl and other substances (Comparative Examples 2 to 4).

Referring to FIG. 2, it can be seen that a measured absorbance of the glass substrate of the example was lower than an absorbance of the glass substrates of Comparative Example 2 and Comparative Example 3. In particular, it was seen that cleaning with a cleaning solution containing an acid was not always better than cleaning with a standard cleaning solution, judging from the fact that the absorbance of Comparative Example 2 was lower than the absorbance of Comparative Example 3. In other words, in the case of the glass substrate of the example, the measured absorbance was lower than those of the comparative examples. Since the measured absorbance was lower in glass substrates that contained less by-products adsorbed thereto, it could be seen, through comparison of absorbance values, that there were less by-products formed on the surface of the glass substrate of the example than on the surface of the glass substrates of Comparative Examples 2 and 3. Also, even though the absorbance of Comparative Example 4 does not seem much different from the absorbance value of the example in the graph, when the actual content of by-product was measured, the result was lower in the glass substrate of the example in comparison to the by-product level of the glass substrate of Comparative Example 4.

### Comparison of Transmittance of Example and Comparative Examples

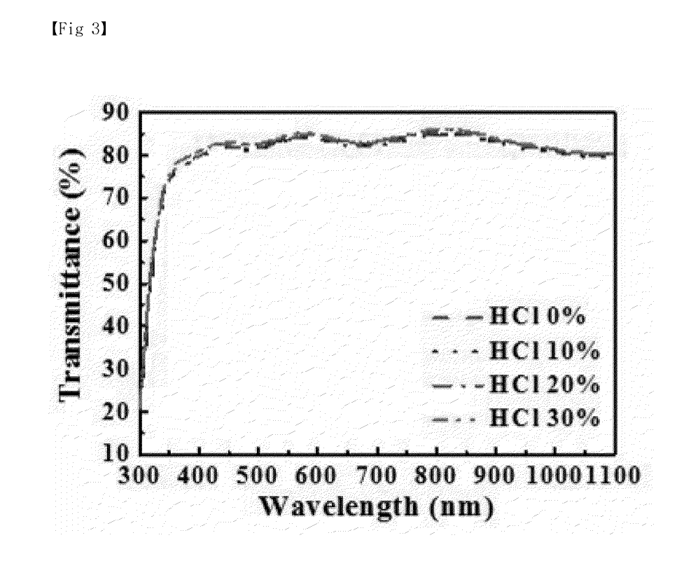

FIG. 3 is a graph showing measured transmittance of a glass substrate that was cleaned with a cleaning solution. The results are shown at various concentrations of HCl contained in the cleaning solution.

Referring to FIG. 3, when the glass substrate was cleaned using a cleaning solution with a high content of HCl, a shift occurred in a wavelength range of 300 to 500 nm, which corresponds to a short-wavelength region. This was attributed to an increased amount of HCl in the etching solution, and with close examination it can be seen that the measured value of transmittance is higher than the glass substrate that was cleaned with a cleaning solution containing no acids.

While exemplary embodiments of the present invention have been described above, the invention is not limited to the aforementioned specific exemplary embodiments. Those skilled in the art may variously modify the invention without departing from the gist of the invention claimed by the appended claims and the modifications are within the protective scope of the claims.

What is claimed is:

1. A method of etching a glass substrate, the method comprising:
etching the glass substrate using an etching solution that includes hydrofluoric acid (HF) and hydrochloric acid (HCl); and
cleaning the glass substrate with a cleaning solution that includes HCl.

2. The method of claim 1, wherein one or more by-products are formed on the glass substrate, the one or more by-products include any one or more among SiF₆, SiH₆, SiHF₅, and are removed from the glass substrate.

3. The method of claim 1, wherein a roughness of a surface of the glass substrate is reduced.

4. The method of claim 1, wherein the etching solution includes the HCl at 300 parts by weight or more with respect to 100 parts by weight of the HF.

5. The method of claim 1, further comprising:
forming a mask that is made of polymer particles by immersing the glass substrate in a solution that includes polymer particles, removing the glass substrate from the solution, and then drying the glass substrate.

6. The method of claim 1, wherein the cleaning solution further includes any one or more among HF and acetic acid (CH₃COOH).

7. A thin-film solar cell comprising:
the glass substrate Of claim 1.

8. The thin-film solar cell of claim 7, wherein a transparent electrode layer is deposited on the glass substrate.

9. The thin-film solar cell of claim 8, wherein the transparent electrode layer includes any one or more among zinc oxide (ZnO), aluminum-doped zinc oxide (AZO), gallium-doped zinc oxide (GZO), boron-doped zinc oxide (BZO), indium tin oxide (ITO), indium gallium zinc oxide (IGZO), and zirconium-doped indium tin oxide (ITO:Zr).
